(19) United States
(12) Patent Application Publication
(10) Pub. No.: US 2025/0366233 A1
(43) Pub. Date: Nov. 27, 2025

(54) IMAGE SENSOR AND MANUFACTURING METHOD THEREFOR

(71) Applicant: Samsung Electronics Co., Ltd., Suwon-si (KR)

(72) Inventors: Junoh KIM, Suwon-si (KR); Munhwan KIM, Suwon-si (KR); Haewon LEE, Suwon-si (KR)

(73) Assignee: Samsung Electronics Co., Ltd., Suwon-si (KR)

(21) Appl. No.: 19/198,506

(22) Filed: May 5, 2025

(30) Foreign Application Priority Data
May 21, 2024 (KR) 10-2024-0065863

(51) Int. Cl. H10F 39/00; H10F 39/18

(52) U.S. Cl. CPC H10F 39/80373; H10F 39/014; H10F 39/182

(57) ABSTRACT

An image sensor that includes a substrate including a first surface, and a second surface opposite the first surface; a transfer gate on the first surface of the substrate; a spacer on a sidewall of the transfer gate; and a floating diffusion area inside the substrate, the floating diffusion area being adjacent a first side of the spacer. An edge of the spacer and an edge of the floating diffusion area are at least partially aligned with each other along a height direction that is vertical with the first surface.

### CROSS-REFERENCE TO RELATED APPLICATION

This application claims priority to and the benefit of Korean Patent Application No. 10-2024-0065863 filed in the Korean Intellectual Property Office on May 21, 2024, the entire contents of which are incorporated herein by reference.

### BACKGROUND

The present disclosure relates to image sensors and manufacturing methods thereof.

An image sensor is a semiconductor device that converts an optical image into an electric signal. The image sensors may be classified into a charge coupled device (CCD) and a complementary metal oxide semiconductor (CMOS).

A CMOS image sensor (CIS) has a merit of low power consumption due to low manufacturing cost and small size compared to the CCD image sensor having a high voltage analog circuit, so that the CIS is mainly installed in home appliances, including portable devices such as smart phones and digital cameras.

The pixel array that makes up the CMOS image sensor includes a photoelectric conversion area such as a photodiode for each pixel. The photoelectric conversion area generates the electric signal that varies depending on the amount of incident light, and the CMOS image sensor processes the electric signal to synthesize the image.

The CMOS image sensor may include a plurality of transistors to drive the photoelectric conversion area.

Recently, as the use high resolution images have become more typical, the size of the pixels of an image sensor has decreased and the number of the pixels has increased. Accordingly, fast operation characteristics of the transistors within the image sensor have become advantageous. As the size of the pixel gets smaller, multiple transistors are disposed within the small pixel area, and operation characteristic errors may occur due to the misalignment of the area where the transistors are disposed depending on the pixel, thereby causing characteristic errors in the operation of the transistors within the image sensor.

### SUMMARY

Some example embodiments of the inventive concepts are intended to provide an image sensor and a manufacturing method of the image sensor in which characteristic errors in the operation of the transistors do not occur.

However, problems to be solved by some example embodiments are not limited to the above-described problems, and may be variously expanded in the range of the technical ideas included in some example embodiments.

Some example embodiments of the inventive concepts provide an image sensor that includes a substrate including a first surface and a second surface opposite the first surface; a transfer gate on the first surface of the substrate; a spacer on a sidewall of the transfer gate; and a floating diffusion area inside the substrate and adjacent to the first surface of the substrate. An edge of the spacer and an edge of the floating diffusion area may be at least partially aligned with each other along a height direction that is vertical with the first surface.

Some example embodiments of the inventive concepts further provide an image sensor manufacturing method that includes forming a transfer gate on a first surface of a substrate, the substrate including the first surface and a second surface opposite the first surface; forming a spacer on a sidewall of the transfer gate; and forming a floating diffusion area by doping an impurity on the first surface of the substrate using a mask, the mask having an opening that exposes at least a portion of the transfer gate and the spacer. An edge of the spacer and an edge of the floating diffusion area are at least partially aligned with each other along a height direction that is vertical with the first surface.

According to some example embodiments, it is possible to provide the image sensor and the manufacturing method of the image sensor in which characteristic errors in the operation of the transistors do not occur.

It should be apparent that the effect of the present disclosure is not limited to the above-described effect, but may be variously extended without departing from the spirit and scope of the present disclosure.

### BRIEF DESCRIPTION OF THE DRAWINGS

FIG. 1 is a block diagram schematically showing an image sensor according to some example embodiments.

FIG. 2 is a top plan view showing a part of an image sensor according to some example embodiments.

FIG. 3 is a circuit diagram of an image sensor according to some example embodiments.

FIG. 4 is a top plan view of an image sensor according to some example embodiments.

FIG. 5 is a cross-sectional view taken along a line I-I′ of FIG. 4.

FIG. 6 is a cross-sectional view taken along a line II-II′ of FIG. 4.

FIG. 7 is an enlarged view of some areas of FIG. 6.

FIG. 8 is a cross-sectional view showing a manufacturing method of an image sensor according to some example embodiments.

FIG. 9 is a top plan view showing a manufacturing method of an image sensor according to some example embodiments.

FIG. 10 is a top plan view of an image sensor according to some example embodiments.

FIG. 11 is an enlarged view of some areas of FIG. 10.

FIG. 12 is a top plan view of an image sensor according to some example embodiments.

FIG. 13 is an enlarged view of some areas of FIG. 12.

### DETAILED DESCRIPTION

The present disclosure will be described more fully hereinafter with reference to the accompanying drawings, in which some example embodiments of the disclosure are shown. As those skilled in the art would realize, the described some example embodiments may be modified in various different ways, all without departing from the spirit or scope of the present disclosure.

In order to clearly explain the present disclosure, portions that are not directly related to the present disclosure may be omitted, and the same reference numerals are attached to the same or similar constituent elements through the entire specification.

The accompanying drawings are provided in order to allow some example embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

The size and thickness of each element are arbitrarily shown in the drawings, and the present disclosure is not necessarily limited thereto, and in the drawings, the thickness of layers, films, panels, areas, etc., are exaggerated for clarity and better understanding.

It will be understood that when an element such as a layer, film, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” means viewing a target portion from the top, and the phrase “in a cross-sectional view” means viewing a cross-section formed by vertically cutting a target portion from the side.

The expression “connected to” in the entire specification not only means that two or more constituent elements are directly connected, but also means that two or more constituent elements are indirectly connected through other constituent elements, physically connected to, or electrically connected, or being referred to by different names depending on the position or function, but is integral.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, some example embodiments and variations are described in detail with reference to drawings.

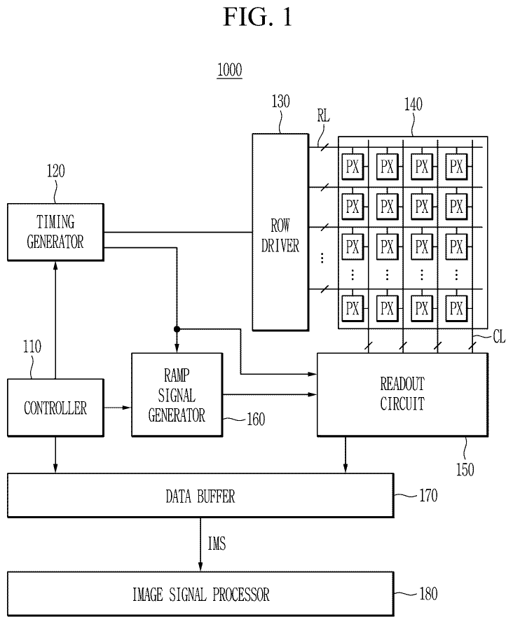

An image sensor according to some example embodiments is briefly described with reference to FIG. 1. FIG. 1 is a block diagram schematically showing an image sensor according to some example embodiments.

Referring to FIG. 1, an image sensor 1000 according to some example embodiments may include a pixel array 140 and a logic circuit that controls the pixel array 140.

The logic circuit is a circuit for controlling the pixel array 140 and may include, for example, a controller 110, a timing generator 120, a row driver 130, a readout circuit 150, a ramp signal generator 160, and a data buffer 170.

The image sensor 1000 may further include an image signal processor 180, and according to some example embodiments, the image signal processor 180 may be disposed outside the image sensor 1000. The image sensor 1000 may generate an image signal by converting light received from the outside into an electric signal. The image signal may be provided to the image signal processor 180.

The image sensor 1000 may be mounted on an electronic device with an image or optical sensing function. For example, the image sensor 1000 may be mounted on electronic devices such as cameras, smart phones, wearable devices, Internet of Things (IoT) devices, home appliances, tablet PCs (personal computers), navigation, drones, and advanced driver assistance systems (ADAS). The image sensor 1000 may be mounted on electronic devices that are included as components in vehicles, furniture, manufacturing facilities, doors, and various measuring devices.

The pixel array 140 may include a plurality of pixels PX, a plurality of row lines RL, and a plurality of column lines CL respectively connected to the plurality of pixels PX.

In some example embodiments, each pixel PX may include at least one photoelectric conversion area. The photoelectric conversion area may detect incident light and convert the incident light into an electric signal according to the amount of light, that is, a plurality of analog pixel signals.

The photoelectric conversion area may be a photodiode, a pinned diode, etc. The photoelectric conversion area may be a single-photon avalanche diode (SPAD) applied to a 3D sensor pixel.

The level of the analog pixel signal output from the photoelectric conversion area may be proportional to the amount of charge output from the photoelectric conversion area. That is, the level of the analog pixel signal output from the photoelectric conversion area may be determined according to the amount of light received into the pixel array 140.

The plurality of row lines RL may be connected to the plurality of pixels PX. For example, the control signal output from the row driver 130 to the row line RL may be transmitted to the gate of the transistor of the plurality of pixels PX connected to the corresponding row line RL. The column line CL may be across the row line RL and may be connected to plurality of pixels PX. The plurality of pixel signals output from the plurality of pixels PX may be transmitted to the readout circuit 150 through the plurality of column lines CL.

The controller 110 may control the operation timing of each of the components 120, 130, 150, 160, 170 described above by using control signals.

In some example embodiments, the controller 110 may receive a mode signal indicating an imaging mode from an application processor and generally control the image sensor 1000 based on the received mode signal. For example, the application processor determines the imaging mode of the image sensor 1000 according to various scenarios such as an illumination of an imaging environment, a user's resolution setting, and a sensing or learned state, and provides the determined result to the controller 110 as the mode signal.

The controller 110 may control the plurality of pixels PX of the pixel array 140 to output the pixel signals according to the imaging mode, the pixel array 140 may output the pixel signals for each of the plurality of pixels PX or the pixel signals for some of the plurality of pixels PX, and the readout circuit 150 may sample and process the pixel signals received from the pixel array 140.

The timing generator 120 may generate a signal that serves as a reference for the operation timing of the components of the image sensor 1000. The timing generator 120 may control the timing of the row driver 130, the readout circuit 150, and the ramp signal generator 160. The timing generator 120 may provide a control signal that controls the timing of the row driver 130, the readout circuit 150, and the ramp signal generator 160.

The row driver 130 may generate the control signal to drive the pixel array 140 in response to the control signal of the timing generator 120, and provide the control signal to the plurality of pixels PX of the pixel array 140 through the plurality of row lines RL.

In some example embodiments, the row driver 130 may control the pixel PX to detect the incident light by a row line unit. The row line unit may include at least one row line RL. For example, the row driver 130 may generate a transfer signal that controls a transfer transistor, a reset control signal that controls a reset transistor, a selection control signal that controls a selection transistor, etc., and provide them to the pixel array 140.

The readout circuit 150 may convert the pixel signal (or the electric signal) from the pixel PX connected to the row line RL selected among the plurality of pixels PX into a pixel value representing the amount of light in response to the control signal from the timing generator 120.

The readout circuit 150 may convert the pixel signal output through the corresponding column line CL into the pixel value. For example, the readout circuit 150 may convert the pixel signal to the pixel value by comparing the ramp signal and the pixel signal. The pixel value may be an image data with plurality of bits. For example, the readout circuit 150 may include a selector, a plurality of comparators, and a plurality of counter circuits.

The ramp signal generator 160 may generate a reference signal to be transmitted to the readout circuit 150. The ramp signal generator 160 may include a current source, a resistor, and a capacitor. As the ramp signal generator 160 controls a ramp voltage, which is the voltage applied to the ramp resistor, by adjusting the current size of the variable current source or the resistance value of the variable resistor, it is possible to generate a plurality of ramp signals that fall or rise with a slope determined by the current size of the variable current source or the resistance value of the variable resistor.

The data buffer 170 stores the pixel value of the plurality of pixels PX connected to the selected column line CL transmitted from the readout circuit 150, and outputs the stored pixel value in response to an enable signal from the controller 110.

The image signal processor 180 may perform an image signal processing on the image signal received from the data buffer 170. For example, the image signal processor 180 may receive a plurality of image signals from the data buffer 170 and synthesize the received image signals to generate one image.

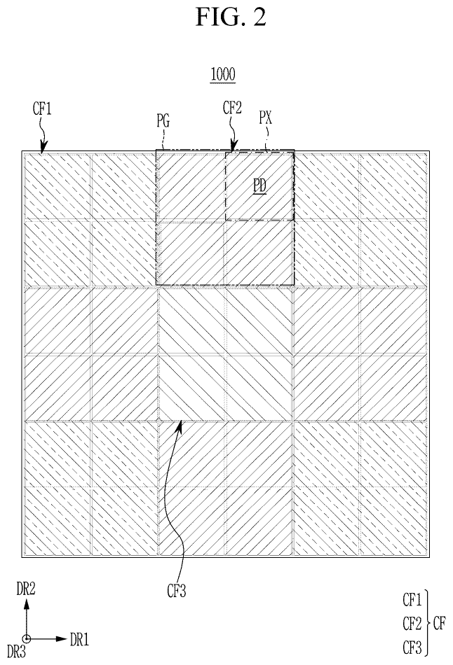

According to some example embodiments, the pixel arrangement of the image sensor is explained with reference to FIG. 2. FIG. 2 is a top plan view showing a part of an image sensor according to some example embodiments.

The image sensor 1000 according to some example embodiments may include pixel groups PG, photoelectric conversion areas PD, color filters CF, and other circuits necessary for the operation of the image sensor 1000.

The plurality of pixels PXs may each include one photoelectric conversion area PD. The photoelectric conversion area PD may include a photodiode, but some example embodiments are not limited thereto.

The plurality of pixels PX may be grouped in a form of a plurality of columns and a plurality of rows to form one unit pixel group PG.

The pixel group PG that overlaps with a first color filter CF1 may detect light of a first color, the pixel group PG that overlaps with a second color filter CF2 may detect light of a second color that is different from the first color, and the pixel group PG that overlaps with a third color filter CF3 may detect light of a third color that is different from the first color and the second color. According to some example embodiments, the image sensor 1000 may further include a pixel group that detects all visible rays.

Each of the plurality of pixel group PG may include N×M pixels PX in an N×M array. The N and the M may each independently be integers greater than 1. For example, the N and the M are each 2 and it may have a pixel arrangement of a 2×2 Tetra structure on a plane. That is, each of the plurality of pixel groups PG may include the pixels PX arranged in a 2×2 shape on a plane.

For example, the plurality of pixels PX arranged in the array direction of the column line CL and the plurality of pixels PX arranged in the array direction of the row line RL may form one unit pixel group PG. For example, one unit pixel group PG includes the plurality of pixels PX arranged in the form of two columns and two rows, and one unit pixel group PG may output one analog pixel signal. However, some example embodiments are not limited to this, and the number of the pixels PX included in one pixel group PG may be modified in various ways.

According to some example embodiments, the image sensor 1000 may further include micro lenses, and at least one micro lens may be disposed in each pixel group PG.

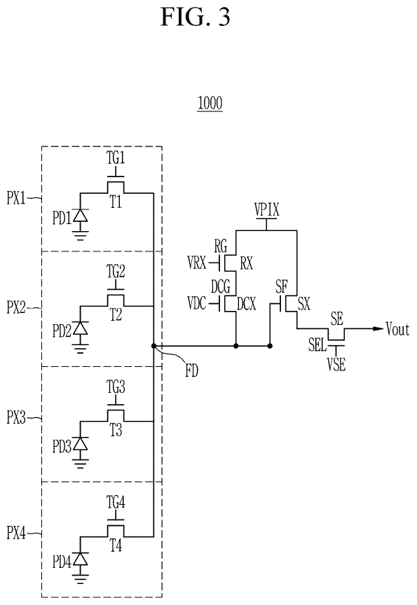

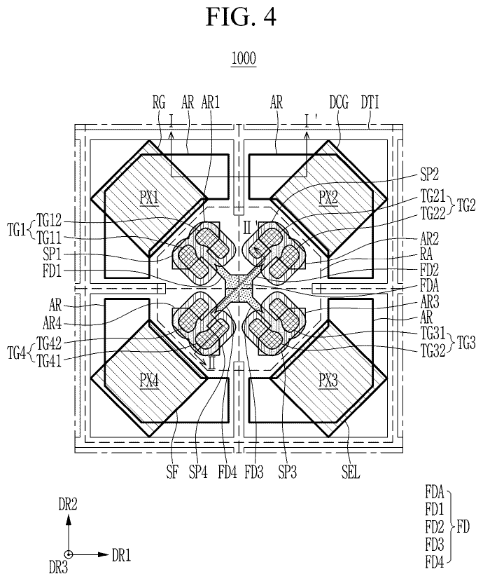

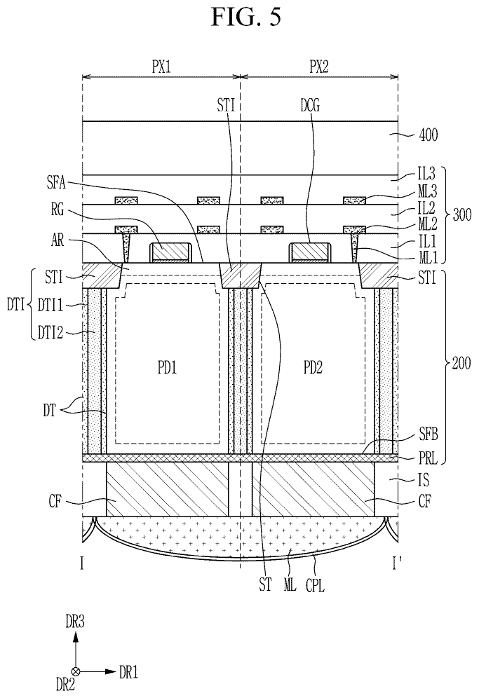

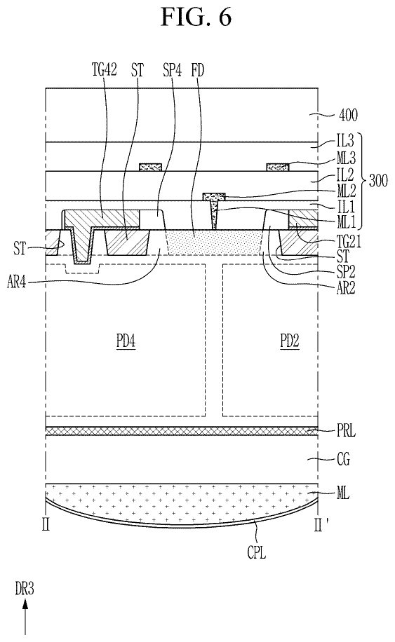

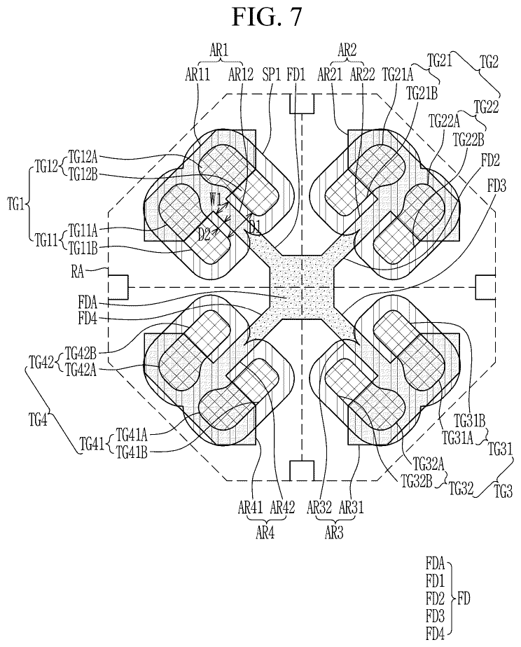

According to some example embodiments, one pixel area of the image sensor is explained with reference to FIG. 3 to FIG. 7 along with FIG. 2. FIG. 3 is a circuit diagram of an image sensor according to some example embodiments, FIG. 4 is a top plan view of an image sensor according to some example embodiments, FIG. 5 is a cross-sectional view taken along a line I-I′ of FIG. 4, IG. 6 is a cross-sectional view taken along a line II-II′ of FIG. 4, and FIG. 7 is an enlarged view of some areas of FIG. 6.

Referring to FIG. 3 along with FIG. 2, the pixel group PG of the image sensor 1000 according to some example embodiments may include pixels PX1, PX2, PX3, and PX4, photoelectric conversion areas PD1, PD2, PD3, and PD4, transfer transistors T1, T2, T3, and T4, a reset transistor RX, a dual conversion transistor DCX, a source follower transistor SX, and a selection transistor SE. As previously described, the pixel group PG is shown to include four pixels PX1, PX2, PX3, and PX4 including the photoelectric conversion areas PD1, PD2, PD3, and PD4, but some example embodiments are not limited thereto.

The first pixel PX1 may include a first photoelectric conversion area PD1 and a first transfer transistor T1, the second pixel PX2 may include a second photoelectric conversion area PD2 and a second transfer transistor T2, the third pixel PX3 may include a third photoelectric conversion area PD3 and a third transfer transistor T3, and the fourth pixel PX4 may include a fourth photoelectric conversion area PD4 and a fourth transfer transistor T4.

The pixels PX1, PX2, PX3, and PX4 may share a floating diffusion area FD.

The pixels PX1, PX2, PX3, and PX4 may share the reset transistor RX, the dual conversion transistor DCX, the source follower transistor SX, and the selection transistor SE.

The floating diffusion area FD may accumulate charges corresponding to the amount of incident light.

While the transfer transistors T1, T2, T3, and T4 are turned on by transfer signals, respectively, the floating diffusion area FD may receive and accumulate charges from the photoelectric conversion areas PD1, PD2, PD3, and PD4.

The reset transistor RX may be driven by a reset signal VRX and provide a power voltage to the floating diffusion area FD. Accordingly, the charges accumulated in the floating diffusion area FD may be moved to the power voltage VPIX terminal, and the voltage of the floating diffusion area FD may be reset.

The source follower transistor SX may be connected between the power voltage VPIX and the selection transistor SE. The source follower transistor SX may output an output signal Vout to the selection transistor SE based on the voltage level of the floating diffusion area FD. The selection transistor SE may be driven by the selection signal VSE, and when the selection transistor SE is turned on, the output signal Vout may be output to the readout circuit 150 through the column line CL.

The dual conversion transistor DCX may be connected between the floating diffusion area FD and the reset transistor RX. When the dual conversion transistor DCX is turned off by the dual conversion signal VDC, a full well capacity (FWC) of each pixel PX1, PX2, PX3, and PX4 may be the capacitance of the floating diffusion area FD. When the dual conversion transistor DCX is turned on by the dual conversion signal VDC, the FWC of each pixel PX1, PX2, PX3, and PX4 may increase than the capacitance of the floating diffusion area FD. Depending on the on/off of the dual conversion transistor DCX, a conversion gain of each pixel PX1, PX2, PX3, and PX4 may be changed.

The structure of the image sensor 1000 according to some example embodiments will be described in more detail with reference to FIG. 4 to FIG. 6 along with FIG. 2 and FIG. 3.

Referring to FIG. 4, according to some example embodiments, the image sensor 1000 may include the pixel group PG including the first pixel PX1, the second pixel PX2, the third pixel PX3, and the fourth pixel PX4 arranged along a clockwise direction.

An isolation pattern DTI may be disposed to surround the edges of the photoelectric conversion areas of the plurality of pixels PX1, PX2, PX3, and PX4. The isolation pattern DTI may be disposed at least in a part between the multiple pixels PX1, PX2, PX3, and PX4.

The isolation pattern DTI may limit and/or prevent a crosstalk between the photoelectric conversion areas of the pixels PX1, PX2, PX3, and PX4.

Referring to FIG. 4 to FIG. 6, the image sensor 1000 may include a substrate 200. The substrate 200 may include silicon (Si), germanium (Ge), or silicon (Si)-germanium (Ge). The substrate 200 may include gallium arsenide (GaAs), indium phosphorus (InP), gallium phosphorus (GaP), indium arsenide (InAs), indium antimony (InSb), or indium gallium arsenide (InGaAs). The substrate 200 may include zinc telluride (ZnTe), or sulfide cadmium (CdS).

The substrate 200 may be a bulk silicon or a silicon-on-insulator (SOI). The substrate 200 may be a silicon substrate, or may include other materials, for example, silicon germanium, indium antimony, lead tellurium compound, indium arsenide, indium phosphide, gallium arsenide or gallium antimony. Alternatively, the substrate 200 may be an epitaxial layer formed on a base substrate.

The substrate 200 may be doped with an impurity of a first conductivity type. For example, the first conductivity type may be a P-type.

The substrate 200 may include a first surface SFA and a second surface SFB facing each other.

The substrate 200 may include a deep trench DT, and the isolation pattern DTI may be disposed within the deep trench DT of the substrate 200.

The isolation pattern DTI may be disposed within the deep trench DT. In an embodiment, the deep trench DT may be extended to or from a shallow trench ST. In an embodiment, the isolation pattern DTI may include a shallow trench isolation pattern STI in the shallow trench ST.

As previously described, the isolation pattern DTI may be disposed on the edge of the photoelectric conversion areas of the pixels PX1, PX2, PX3, and PX4 and at least part of the photoelectric conversion areas between the multiple pixels PX1, PX2, PX3, and PX4.

The isolation pattern DTI may penetrate the substrate 200 from the first surface SFA of the substrate 200 to the second surface SFB.

The isolation pattern DTI may include a first pattern DTI1, a second pattern DTI2, and the shallow trench isolation pattern STI. The first pattern DTI1 may cover the inner sidewall of the deep trench DT. The second pattern DTI2 may fill the inner part of the deep trench DT. The shallow trench isolation pattern STI may be located on the first pattern DTI1 and the second pattern DTI2.

The first pattern DTI1 and the second pattern DTI2 may penetrate the substrate 200 from the second surface SFB to the shallow trench isolation pattern STI. The second pattern DTI2 may be separated from the substrate 200 by the first pattern DTI1. In some embodiments, the first pattern DTI1 of the isolation pattern DTI may be connected to the shallow trench isolation pattern STI, and the shallow trench isolation pattern STI and the third pattern DTI3 may be indistinguishable. In some embodiments, the second pattern DTI2 may extend into a part of the shallow trench isolation pattern STI.

The first pattern DTI1 and the shallow trench isolation pattern STI may include silicon oxide, silicon nitride, and silicon oxynitride. The first pattern DTI1 may include a metal oxide such as hafnium oxide, aluminum oxide, tantalum oxide, etc., and the first pattern DTI1 may act as a negative fixed charge layer. The second pattern DTI2 may include a semiconductor material such as polysilicon doped for example with an N-type or a P-type.

Within the substrate 200, the photoelectric conversion areas PD1, PD2, PD3, and PD4 corresponding to each pixel PX1, PX2, PX3, and PX4 may be disposed.

Light incident from the outside may be converted into electrical signals in the photoelectric conversion areas PD1, PD2, PD3, and PD4. The photoelectric conversion areas PD1, PD2, PD3, and PD4 may include a photodiode formed inside the substrate 200. The photoelectric conversion areas PD1, PD2, PD3, and PD4 may be doped with a conductive impurity that is different from the conductive impurity doped on the substrate 200.

The photoelectric conversion areas PD1, PD2, PD3, and PD4 may be doped with a second conductivity type impurity that is different from the first conductivity type impurity doped on the substrate 200. For example, the substrate 200 may be doped with P-type impurities, and the photoelectric conversion areas PD1, PD2, PD3, and PD4 may be doped with N-type impurities.

The N-type impurity area of the photoelectric conversion areas PD1, PD2, PD3, and PD4 may form a PN junction with the P-type impurity area of the surrounding substrate 200 to form a photodiode, and when light is incident, an electron-hole pair may be created by the PN junction.

The isolation pattern DTI may be disposed in at least part between the photoelectric conversion areas PD1, PD2, PD3, and PD4 corresponding to the plurality of pixels PX1, PX2, PX3, and PX4, and the photoelectric conversion areas PD1, PD2, PD3, and PD4 corresponding to the plurality of pixels PX1, PX2, PX3, and PX4, respectively, may be at least partially separated from each other by the isolation pattern DTI. The isolation pattern DTI may electrically and optically isolate the photoelectric conversion areas PD1, PD2, PD3, and PD4 adjacent to each other.

The substrate 200 may include the shallow trench ST, and the shallow trench isolation pattern STI may be disposed within the shallow trench ST of the substrate 200. The shallow trench ST may be disposed in a portion of the substrate 200 without penetrating the substrate 200 from the first surface SFA of the substrate 200. Along the third direction DR3, which is the height direction, the depth of the shallow trench ST may be smaller than the depth of the deep trench DT. The shallow trench isolation pattern STI may include silicon oxide, silicon nitride, or a combination thereof.

Differently, the shallow trench isolation pattern STI may be an area in which the impurity of the same first conductivity type as the impurity doped in the substrate 200 is doped with a higher concentration than the doping concentration of the impurity doped in the substrate 200.

In an embodiment, the isolation pattern DTI may include the shallow trench isolation pattern STI.

A plurality of gates TG1, TG2, TG3, TG4, RG, DCG, SF, and SEL may be disposed on the first surface SFA of the substrate 200.

The plurality of pixels PX1, PX2, PX3, and PX4 may each include active areas AR, AR1, AR2, AR3, and AR4 disposed within the substrate 200 adjacent to the first surface SFA of the substrate 200. Each of the active areas AR, AR1, AR2, AR3, and AR4 may be distinguished by the shallow trench isolation pattern STI.

The substrate 200 may include a floating diffusion area FD and ground areas (not shown) disposed adjacent to the first surface SFA.

The floating diffusion area FD may be adjacent to the transfer gates TG1, TG2, TG3, and TG4, and the floating diffusion area FD may be doped with an impurity of a second conductivity type that is different from the impurity of the first conductivity type doped on the substrate 200.

The ground areas may be doped with the same conductive impurity as the conductive impurity doped in the substrate 200, and the concentration of the doped conductive impurity may be higher than the other concentration of the substrates 200.

The active areas AR of the plurality of pixels PX1, PX2, PX3, and PX4 may be an active area for the operation of the plurality of transistors.

The plurality of gates TG1, TG2, TG3, TG4, RG, DCG, SF, and SEL may be disposed above the active areas AR, AR1, AR2, AR3, and AR4 of the plurality of pixels PX1, PX2, PX3, and PX4.

The plurality of gates TG1, TG2, TG3, TG4, RG, DCG, SF, and SEL, and the floating diffusion area FD may form the transfer transistors T1, T2, T3, and T4, the source follower transistor SX, the selection transistor SE, the reset transistor RX, and the dual conversion transistor DCX. The ground areas may be a ground pattern for grounding at least one of the transfer transistors T1, T2, T3, and T4, the selection transistor SE, the reset transistor RX, and the dual conversion transistor DCX.

A first structure 300 may be disposed on the first surface SFA of the substrate 200. The first structure 300 may include a plurality of vias ML1, a plurality of wire layers ML2 and ML3, and a plurality of insulating layers IL1, IL2, and IL3. The plurality of insulating layers IL1, IL2, and IL3 may electrically separate the plurality of vias ML1 and the plurality of wire layers ML2 and ML3.

The plurality of vias ML1 and the plurality of wire layers ML2 and ML3 may be electrically connected to the transistors on the first surface SFA of the substrate 200.

The plurality of vias ML1, and the plurality of wire layers ML2 and ML3 may include tungsten, aluminum, copper, tungsten silicide, titanium silicide, tungsten nitride, titanium nitride, doped polysilicon, etc.

The plurality of insulating layers IL1, IL2, and IL3 may include insulating materials such as silicon oxide, silicon nitride, silicon oxynitride, and low-k materials. The low dielectric material, for example, may include at least one among FOX (Flowable Oxide), TOSZ (Torene SilaZene), USG (Undoped Silica glass), BSG (Borosilica glass), PSG (PhosphoSilica glass), BPSG (BoroPhosphoSilica glass), PETEOS (Plasma Enhanced tetra-ethyl Ortho Silicate), FSG (Fluoride silicate glass), CDO (Carbon Doped silicon Oxide), Xerogel, Aerogel, Amorphous Fluorinated Carbon, OSG (Organo silicate glass), Parylene, BCB (bis-benzocyclobutenes), SiLK, polyimide, porous polymeric material, and combinations thereof.

The image sensor 1000 may further include a supporting substrate 400 disposed above the first structure 300, but the supporting substrate 400 may be omitted. An additional adhesive member (not shown) may be disposed between the supporting substrate 400 and the first structure 300.

An anti-reflection layer PRL may be disposed on the second surface SFB of the substrate 200. The anti-reflection layer PRL may cover the second surface SFB of the substrate 200 and the isolation pattern DTI.

The anti-reflection layer PRL may include hafnium oxide (HfO₂), silicon oxide (SiO₂), silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), yttrium oxide (Y₂O₃), or a combination thereof.

In some example embodiments, the anti-reflection layer PRL may include a plurality of layers including different materials and having different thicknesses. For example, the anti-reflection layer PRL may include first to third anti-reflection layers sequentially stacked on the second surface SFB of the substrate 200.

The first anti-reflection layer may be a fixed charge layer with a negative fixed charge. A hole accumulation may occur around the fixed charge layer, thereby effectively reducing an occurrence of a dark current and white spots.

The third anti-reflection layer is a metal oxide including at least one of hafnium (Hf), zirconium (Zr), aluminum (Al), tantalum (Ta), titanium (Ti), and yttrium (Y) or a metal fluoride. For example, the first anti-reflection layer and the third anti-reflection layer may include a hafnium oxide layer, and the second anti-reflection layer may include silicon oxide and/or silicon nitride. However, in some example embodiments, the number and relative thickness of the layers constituting the anti-reflection layer PRL may be varied.

In some example embodiments, the anti-reflection layer PRL may further include a silicon nitride layer disposed between the second anti-reflection layer and the third anti-reflection layer.

Fence patterns IS may surround the color filters CF.

The fence patterns IS may include a low refractive index material. The low refractive index material may have a refractive index greater than approximately 1.0 and less than or equal to approximately 1.4. For example, the low refractive index material may include poly(methyl methacrylate) (PMMA), silicon acrylate (silicon acrylate), cellulose acetate butyrate (CAB), silica (silica), or fluoro-silicon acrylate (FSA). For example, the low refractive index material may include a polymer material with distributed silica (SiOx) particles.

If the fence patterns IS include the low refractive index material with a relatively low refractive index, light incident toward the fence patterns IS may be totally and/or mostly reflected, and directed toward the center of each pixel area PX1, PX2, PX3, and PX4.

The fence patterns IS may limit and/or prevent light incident obliquely into the color filter CF disposed in one of the plurality of pixel areas PX1, PX2, PX3, and PX4 from entering the color filter CF disposed on another adjacent pixel area, accordingly, the crosstalk between the plurality of pixel areas PX1, PX2, PX3, and PX4 may be limited and/or prevented.

The plurality of color filters CF may be disposed on the anti-reflection layer PRL. At least part of the color filters CF may be separated from each other by the fence pattern IS. The plurality of color filters CF may include, for example, a green filter, a blue filter, and a red filter. The plurality of color filters CF may include, for example, cyan, magenta, or yellow.

A micro lens ML may be disposed on the color filter CF and the fence pattern IS.

The micro lens ML may be transparent. The micro lens ML may be formed of a resin-based material such as, for example, styrene-based resin, acryl-based resin, styrene-acryl copolymerization-based resin, or siloxane-based resin.

The micro lens ML may condense the incident light, and the collected light may be incident on the photoelectric conversion areas PD1, PD2, PD3, and PD4 through the color filter CF.

A capping layer CPL may be disposed on the micro lens ML to protect the micro lens ML.

Some areas of the image sensor 1000 will be explained in more detail with reference to FIG. 7 along with FIG. 4 and FIG. 6. FIG. 7 is an enlarged view of a part of some area RA in FIG. 4.

According to some example embodiments, the floating diffusion area FD of the image sensor 1000 may include a central floating diffusion area FDA disposed in the center of the area occupied by the first pixel PX1, the second pixel PX2, the third pixel PX3, and the fourth pixel PX4 across the first pixel PX1, the second pixel PX2, the third pixel PX3, and the fourth pixel PX4, a first extending floating diffusion area FD1 disposed at first pixel PX1 and connected to the first active area AR1 of the first pixel PX1, a second extending floating diffusion area FD2, disposed at the second pixel PX2 and connected to the second active area AR2 of the second pixel PX2, a third extending floating diffusion area FD3 disposed at third pixel PX3 and connected to the third active area AR3 of the third pixel PX3, and a fourth extending floating diffusion area FD4 disposed at the fourth pixel PX4 and connected to the fourth active area AR4 of the fourth pixel PX4. The floating diffusion area FD of the first pixel PX1, the floating diffusion area FD of the second pixel PX2, the floating diffusion area FD of the third pixel PX3, and the floating diffusion area FD of the fourth pixel PX4 may be connected to the central floating diffusion area FDA and may be integrally formed.

The central floating diffusion area FDA of the floating diffusion area FD may be disposed at the center of the first pixel PX1, the second pixel PX2, the third pixel PX3, and the fourth pixel PX4. In an embodiment, at least part of the isolation pattern DTI may be not disposed in the position corresponding to the floating diffusion area FD. In an embodiment, along the third direction DR3 which is the height direction, the first pattern DTI1 and the second pattern DTI2 of the isolation pattern DTI may overlap the central floating diffusion area FDA of the floating diffusion area FD and the shallow trench isolation pattern STI of the isolation pattern DTI may not overlap the central floating diffusion area FDA.

The first active area AR1 of the first pixel PX1 may include an active portion AR11 that overlaps the first transfer gate TG1 and a connection part AR12 disposed between the first extending floating diffusion area FD1 and the active portion AR11. The second active area AR2 of the second pixel PX2 may include an active portion AR21 that overlaps the second transfer gate TG2 and a connection part AR22 disposed between the second extending floating diffusion area FD2 and the active portion AR21. The third active area AR3 of the third pixel PX3 may include an active portion AR31 that overlaps the third transfer gate TG3 and a connection part AR32 disposed between the third extending floating diffusion area FD3 and the active portion AR31. The fourth active area AR4 of the fourth pixel PX4 may include an active portion AR41 that overlaps the fourth transfer gate TG4 and a connection part AR42 disposed between the fourth extending floating diffusion area FD4 and the active portion AR41.

The first transfer gate TG1 disposed at the first pixel PX1 may include two transfer gates TG11 and TG12, two transfer gates TG11 and TG12 may include gate areas TG11A and TG12A that overlap the active portion AR11 of the first active area AR1, and extending parts TG11B and TG12B extending in the same direction as the direction in which the connection part AR12 of the first active area AR1 extends on a plane where the first direction DR1 and the second direction DR2 intersect, and the connection part AR12 may be disposed between the extending parts TG11B and TG12B on a plane where the first direction DR1 and the second direction DR2 intersect.

The second transfer gate TG2 disposed at the second pixel PX2 may include two transfer gates TG21 and TG22, the two transfer gates TG21 and TG22 may include gate areas TG21A and TG22A that overlap the active portion AR21 of the second active area AR2, and extending parts TG21B and TG22B that extend in the same direction as the connection part AR22 of the second active area AR2, and the connection part AR22 may be disposed between the extending parts TG21B and TG22B on a plane where the first direction DR1 and the second direction DR2 intersect.

The third transfer gate TG3 disposed at the third pixel PX3 may include two transfer gates TG31 and TG32, two transfer gates TG31 and TG32 may include gate areas TG31A and TG32A that overlap the active portion AR31 of the third active area AR3 and extending parts TG31B and TG32B that extend in the same direction as the direction in which the connection part AR32 of the third active area AR3 extends, and the connection part AR32 may be disposed between the extending parts TG31B and TG32B on a plane where the first direction DR1 and the second direction DR2 intersect.

Fourth transfer gate TG4 disposed at the fourth pixel PX4 may include two transfer gates TG41, and TG42, two transfer gates TG41 and TG42 may have gate areas TG41A and TG42A that overlap the active portion AR41 of the fourth active area AR4 and extending parts TG41B and TG42B extending in the same direction as the direction in which the connection part AR42 of the fourth active area AR4 extends, and the connection part AR42 may be disposed between the extending parts TG41B and TG42B on a plane where the first direction DR1 and the second direction DR2 intersect.

The connection part AR12 of the first active area AR1, the connection part AR22 of the second active area AR2, the connection part AR32 of the third active area AR3, and the connection part AR42 of the fourth active area AR4 may each have a first width W1.

On a plane where the first direction DR1 and the second direction DR2 intersect, there may be a first interval D1 between the extending parts TG11B and TG12B of the first transfer gate TG1. Similarly, on a plane where the first direction DR1 and the second direction DR2 intersect, the extending parts TG21B and TG22B of the second transfer gate TG2 may also have the first interval D1 therebetween, the extending parts TG31B and TG32B of the third transfer gate TG3 may also have the first interval D1 therebetween, and the extending parts TG41B and TG42B of the fourth transfer gate TG4 may also have the first interval D1 therebetween.

The first interval D1 may be larger than the first width W1.

On a plane where first direction DR1 and second direction DR2 intersect, there may be a second interval D2 between the connection part AR12 of the first active area AR1 and the extending parts TG11B and TG12B of the first transfer gate TG1. Similarly, on a plane where the first direction DR1 and the second direction DR2 intersect, there may also be a second interval D2 between the connection part AR22 of the second active area AR2 and the extending parts TG21B and TG22B of the second transfer gate TG2, there may also be a second interval D2 between the connection part AR32 of the third active area AR3 and the extending parts TG31B and TG32B of the third transfer gate TG3, and there may also be a second interval D2 between the connection part AR42 of the fourth active area AR4 and the extending parts TG41B and TG42B of the fourth transfer gate TG4.

The first spacer SP1 may be disposed on the sidewall of two transfer gates TG11 and TG12 of the first transfer gate TG1 and surround the edge, the second spacer SP2 may be disposed on the sidewall of two transfer gates TG21 and TG22 of the second transfer gate TG2 and surround the edge, the third spacer SP3 may be disposed on the sidewall of two transfer gates TG31 and TG32 of the third transfer gate TG3 and surround the edge, and the fourth spacer SP4 may be disposed on the sidewall of the two transfer gates TG41 and TG42 of the fourth transfer gate TG4 and surround the edge.

On a plane where the first direction DR1 and the second direction DR2 intersect, the first interval D1 between two transfer gates TG11 and TG12, TG21 and TG22, TG31 and TG32, and TG41 and TG42 of the transfer gates TG1, TG2, TG3, and TG4 may advantageously be disposed close enough so that spacers SP1, SP2, SP3, and SP4 may be formed to fill areas between the two transfer gates TG11 and TG12, TG21 and TG22, TG31 and TG32, and TG41 and TG42.

The first width W1 of the connection part AR12 of the first active area AR1, the connection part AR22 of the second active area AR2, the connection part AR32 of the third active area AR3, and the connection part AR42 of the fourth active area AR4 may advantageously be such that that the charge transfer between the floating diffusion area FD and the first to fourth active areas AR1, AR2, AR3, and AR4 is as small as possible.

On a plane where the first direction DR1 and the second direction DR2 intersect, the connection parts AR12, AR22, AR32, and AR42 of the active areas AR1, AR2, AR3, and AR4, and two extending parts TG11B and TG12B, TG21B and TG22B, TG31B and TG32B, TG41B and TG42B extending in the same direction as the connection parts AR12, AR22, AR32, and AR42 are separated to have the second interval D2, so that an electric potential of the connection parts AR12, AR22, AR32, and AR42 of the active areas (AR1, AR2, AR3, AR4 is limited and/or prevented from modulating by two extending parts TG11B and TG12B, TG21B and TG22B, TG31B and TG32B, TG41B and TG42B of the transfer gates TG1, TG2, TG3, and TG4.

The boundary between the connection part AR12 of the first active area AR1 and the first extending floating diffusion area FD1 may overlap or be aligned to the edge of the first spacer SP1 to each other along the height direction DR3. Similarly, the boundary between the connection part AR22 of the second active area AR2 and the second extending floating diffusion area FD2 may overlap or be aligned to the edge of the second spacer SP2 to each other along the height direction DR3, the boundary between the connection part AR32 of the third active area AR3 and the third extending floating diffusion area FD3 may overlap or be aligned to the edge of the third spacer SP3 along the height direction DR3, and the boundary between the connection part AR42 of the fourth active area AR4 and the fourth extending floating diffusion area FD4 may overlap or be aligned to the edge of fourth spacer SP4 to each other along the height direction DR3.

The transfer gates TG1, TG2, TG3, and TG4 may include two extending parts TG11B and TG12B, TG21B and TG22B, TG31B and TG32B, and TG41B and TG42B extending in the same direction as the connection parts AR12, AR22, AR32, and AR42 in the active areas AR1, AR2, AR3, and AR4, the spacers SP1, SP2, SP3, and SP4 may surround the edges of the extending parts TG11B, TG12B, TG21B, TG22B, TG31B, TG32B, TG41B, and TG42B, and the edges of the extending floating diffusion areas FD1, FD2, FD3, and FD4 may overlap or be aligned to the edges of the spacers SP1, SP2, SP3, and SP4 along the height direction DR3.

Therefore, the floating diffusion area FD may be separated from the active portions AR11, AR21, AR31, AR41 of the active areas AR1, AR2, AR3, and AR4) and the gate areas TG11A, TG12A, TG21A, TG22A, TG31A, TG32A, TG41A, and TG42A of the transfer gates TG1, TG2, TG3, and TG4 overlapping the active portions AR11, AR21, AR31, AR41, on a plane formed by the intersection of the first direction DR1 and the second direction DR2. Accordingly, a leakage current in the drain area induced by the gate voltage by the gate areas TG11A, TG12A, TG21A, TG22A, TG31A, TG32A, TG41A, and TG42A of the transfer gates TG1, TG2, TG3, and TG4 (a gate induced drain leakage) may be limited and/or prevented, thereby improving performance and/or reliability of the image sensor 1000.

The edges of the extending floating diffusion areas FD1, FD2, FD3, and FD4 may overlap or align with the edges of the spacers SP1, SP2, SP3, and SP4 along the height direction DR3, so that the distance between the gate areas TG11A, TG12A, TG21A, TG22A, TG31A, TG32A, TG41A, and TG42A of the transfer gates TG1, TG2, TG3, and TG4 and the floating diffusion area FD may be substantially constant. Accordingly, it is possible to reduce an occurrence of a characteristic deviation of the transfer transistors T1, T2, T3, and T4 that may occur due to the distance differences between the transfer gates TG1, TG2, TG3, and TG4 and the floating diffusion area FD, thereby limiting and/or preventing the occurrence of operating characteristic errors between the transfer transistors, and thus improving performance and/or reliability of the image sensor 1000.

As the transfer gates TG1, TG2, TG3, and TG4 include the extending parts TG11B, TG12B, TG21B, TG22B, TG31B, TG32B, TG41B, and TG42B, the area of the transfer gates TG1, TG2, TG3, and TG4 may be increased, and the contact area that the transfer gates TG1, TG2, TG3, and TG4 may be connected to the plurality of vias ML1 and the plurality of wire layers ML2 and ML3 of the first structure 300 may be increased, thereby transmitting stable signals to the transfer gates TG1, TG2, TG3, and TG4, and thus improving performance and/or reliability of the image sensor 1000.

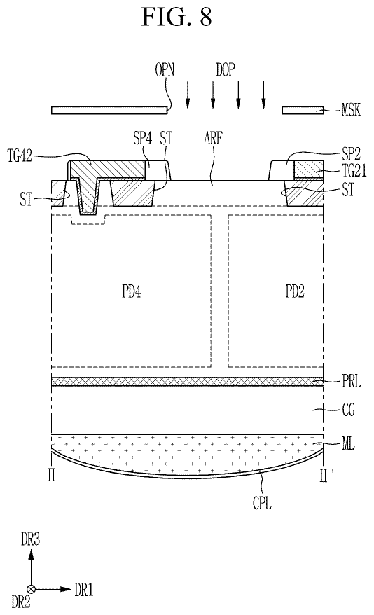

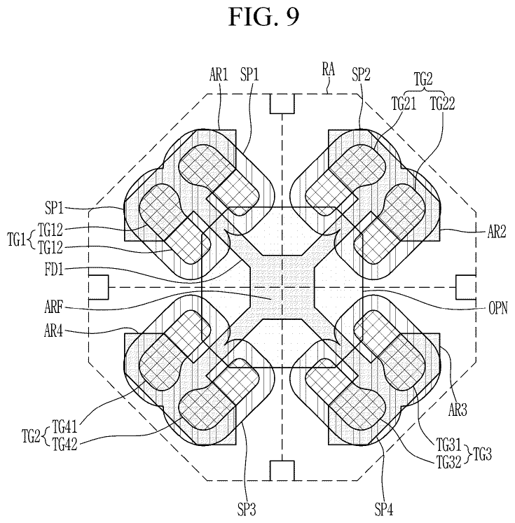

A manufacturing method of the image sensor according to some example embodiments will be described with reference to FIG. 8 and to FIG. 9 along with FIG. 1 to FIG. 7. FIG. 8 is a cross-sectional view showing a manufacturing method of an image sensor according to some example embodiments, and FIG. 9 is a top plan view showing a manufacturing method of an image sensor according to some example embodiments.

Referring to FIG. 8 and FIG. 9, the method for forming the floating diffusion area FD of the image sensor 1000 is explained.

As shown in FIG. 8 and FIG. 9, a first transfer gate TG1, a second transfer gate TG2, a third transfer gate TG3, and a fourth transfer gate TG4 may be formed on a first active area AR1, a second active area AR2, a third active area AR3, and a fourth active area AR4 of a first pixel PX1, and a first spacer SP1, a second spacer SP2, a third spacer SP3, and a fourth spacer SP4 disposed at the sidewall along the edge of the first transfer gate TG1, the second transfer gate TG2, the third transfer gate TG3, and the fourth transfer gate TG4 may be formed, and then in a preliminary active area ARF disposed in an area where a floating diffusion area FD will be formed, a floating diffusion area FD with a doped impurity may be formed by doping an impurity (as indicated by DOP) by using a mask MSK with an opening OPN.

As previously explained, the transfer gates TG1, TG2, TG3, and TG4 include extending parts TG11B, TG12B, TG21B, TG22B, TG31B, TG32B, TG41B, and TG42B extending in the same direction as the connection parts AR12, AR22, AR32, and AR42 of the active areas AR1, AR2, AR3, and AR4, and the spacers SP1, SP2, SP3, and SP4 surround all edges of the extending parts TG11B, TG12B, TG21B, TG22B, TG31B, TG32B, TG41B, and TG42B.

The area of the opening OPN of the mask MSK is larger than the area where the floating diffusion area FD will be formed. For example, the mask MSK may expose at least a portion of the transfer gates TG1, TG2, TG3 and TG4 and the spacers SP1, SP2, SP3 and SP4. However, since the transfer gates TG1, TG2, TG3 and TG4 and the spacers SP1, SP2, SP3 and SP4 may serve as an additional mask during doping of the impurity, the impurity is not doped in areas overlapping the extending parts TG11B, TG12B, TG21B, TG22B, TG31B, TG32B, TG41B, and TG42B of the transfer gates TG1, TG2, TG3, and TG4 and the spacers SP1, SP2, SP3, and SP4, the impurity is not doped in the connection parts AR12 AR22, AR32, AR42 of the active areas AR1, AR2, AR3, and AR4, and the impurity is doped only in areas that do not overlap the extending parts TG11B, TG12B, TG21B, TG22B, TG31B, TG32B, TG41B, and TG42B of the transfer gates TG1, TG2, TG3, and TG4 and the spacers SP1, SP2, SP3, and SP4, thereby forming the extending floating diffusion areas FD1, FD2, FD3, and FD4 and the central floating diffusion area FDA.

If the extending parts TG11B, TG12B, TG21B, TG22B, TG31B, TG32B, TG41B, and TG42B of the transfer gates TG1, TG2, TG3, and TG4 and the spacers SP1, SP2, SP3, and SP4 are not extended to the side of the connection parts AR12 AR22, AR32, and AR42 of the active areas AR1, AR2, AR3, and AR4, an impurity doping for forming the floating diffusion area FD is performed on the area overlapping the opening OPN of the mask MSK, and if an alignment error of the mask MSK occurs, errors of the spaces between the transfer gates TG1, TG2, TG3, and TG4, and the floating diffusion area FDs may also occur. For example, the characteristic deviation of the transfer transistors T1, T2, T3, and T4 may occur due to the distance differences between the transfer gates TG1, TG2, TG3, and TG4 and the floating diffusion area FD.

The transfer gates TG1, TG2, TG3, and TG4 include two extending parts TG11B and TG12B, TG21B and TG22B, TG31B and TG32B, TG41B and TG42B extending in the same direction as the connection parts AR12, AR22, AR32, and AR42 of the active areas AR1, AR2, AR3, and AR4, and the spacers SP1, SP2, SP3, and SP4 may surround the edges of extending parts TG11B, TG12B, TG21B, TG22B, TG31B, TG32B, TG41B, and TG42B.

Therefore, the floating diffusion area FD may be separated from the active portions AR11, AR21, AR31, and AR41 of the active areas AR1, AR2, AR3, and AR4 and the gate areas TG11A, TG12A, TG21A, TG22A, TG31A, TG32A, TG41A, and TG42A of the transfer gates TG1, TG2, TG3, and TG4 overlapping the active portions AR11, AR21, AR31, AR41, on a plane formed by the intersection of the first direction DR1 and the second direction DR2. Through this, the gate induced drain leakage in the drain area induced by the gate voltage due to the gate areas TG11A, TG12A, TG21A, TG22A, TG31A, TG32A, TG41A, and TG42A of the transfer gates TG1, TG2, TG3, and TG4 may be limited and/or prevented.

According to some example embodiments, during the impurity doping process to form the floating diffusion area FD, as the extending parts TG11B, TG12B, TG21B, TG22B, TG31B, TG32B, TG41B, and TG42B of the transfer gates TG1, TG2, TG3, and TG4 and the spacers SP1, SP2, SP3, and SP4 may serve as an additional mask, the boundary between the connection parts AR12, AR22, AR32, and AR42 of the active areas AR1, AR2, AR3, and AR4 and the extending floating diffusion areas FD1, FD2, FD3, and FD4 may overlap or be aligned to the edges of the spacers SP1, SP2, SP3, and SP4 to each other along the height direction DR3. Accordingly, the distance between the gate areas TG11A, TG12A, TG21A, TG22A, TG31A, TG32A, TG41A, and TG42A of the transfer gates TG1, TG2, TG3, and TG4 and the floating diffusion area FD may be substantially constant, and then the occurrence of the characteristic deviation of the transfer transistors T1, T2, T3, and T4 that may be caused by the differences in the distances between the transfer gates TG1, TG2, TG3, and TG4 and the floating diffusion area FD may be limited and/or prevented, thereby limiting and/or preventing the occurrence of the operating characteristic errors between the transfer transistors.

As the transfer gates TG1, TG2, TG3, and TG4 include the extending parts TG11B, TG12B, TG21B, TG22B, TG31B, TG32B, TG41B, and TG42B, the area of the transfer gates TG1, TG2, TG3, and TG4 may be increased, and the contact area that the transfer gates TG1, TG2, TG3, and TG4 may be connected to the plurality of vias ML1 and the plurality of wire layers ML2 and ML3 of the first structure 300 may be increased, thereby transmitting stable signals to the transfer gates TG1, TG2, TG3, and TG4.

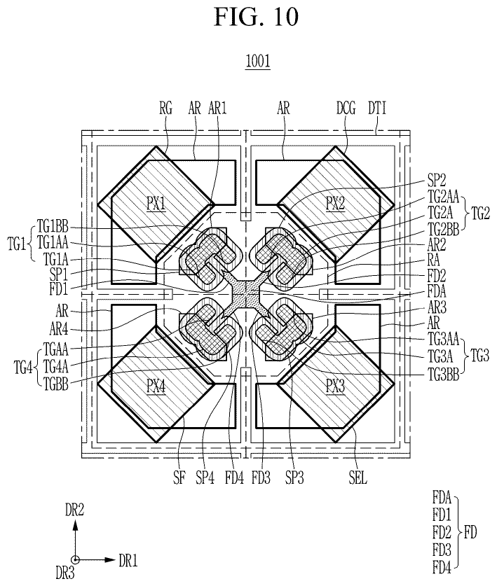

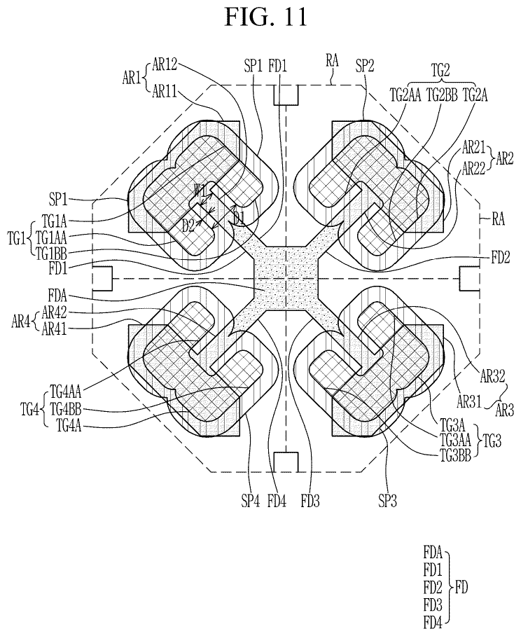

An image sensor 1001 according to some example embodiments is described with reference to FIG. 10 and FIG. 11. FIG. 10 is a top plan view of an image sensor according to some example embodiments. FIG. 11 is an enlarged view of some areas of FIG. 10.

Referring to FIG. 10 and FIG. 11, the image sensor 1001 according to some example embodiments is similar to the image sensor 1000 according to some example embodiments described above. Detailed descriptions of the same components are omitted.

Unlike the image sensor 1000 according to some example embodiments described above, the transfer gates TG1, TG2, TG3, and TG4 of the image sensor 1001 according to some example embodiments as shown in FIGS. 10 and 11 may each include one transfer gate.

The first transfer gate TG1 disposed in the first pixel PX1 may include one gate area TG1A that overlaps the active portion AR11 of the first active area AR1 and extending parts TG1AA and TG1BB that extend in the same direction as the direction in which the connection part AR12 of the first active area AR1 extends from the gate area TG1A and that are spaced apart from each other.

Similarly, the second transfer gate TG2 disposed at the second pixel PX2 may include one gate area TG2A that overlaps the active portion AR21 of the second active area AR2, and extending parts TG2AA and TG2BB that extend in the same direction as the extending direction of the connection part AR22 of the second active area AR2 from the gate area TG2A and that are spaced apart from each other.

The third transfer gate TG3 disposed at the third pixel PX3 may include one gate area TG3A overlapping the active portion AR31 of the third active area AR3, and extending parts TG3AA and TG3BB that extend from the gate area TG3A in the same direction as the direction in which the connection part AR32 of the third active area AR3 extends and that are spaced apart from each other.

The fourth transfer gate TG4 disposed at the fourth pixel PX4 may include one gate area TG4A that overlaps the active portion AR41 of the fourth active area AR4, and extending parts TG4AA and TG4BB that extend from the gate area TG4A in the same direction as the direction in which the connection part AR42 of the fourth active area AR4 extends and that are spaced apart from each other.

Each of the connection parts AR12, AR22, AR32, and AR42 of the active areas AR1, AR2, AR3, and AR4 may have a first width W1, the extending parts TG1AA and TG1BB, TG2AA and TG2BB, TG3AA and TG3BB, TG4AA and TG4BB of the transfer gates TG1, TG2, TG3, and TG4 may have a first interval D1 therebetween, and the first interval D1 may be larger than the first width W1.

Intervals between the extending parts TG1AA and TG1BB, TG2AA and TG2BB, TG3AA and TG3BB, TG4AA and TG4BB of the transfer gates TG1, TG2, TG3, and TG4 and the connection parts AR12, AR22, AR32, and AR42 of the active areas AR1, AR2, AR3, and AR4 may be a second interval D2.

By separating the connection parts AR12, AR22, AR32, and AR42 of the active areas AR1, AR2, AR3, and AR4 and the extending parts TG1AA and TG1BB, TG2AA and TG2BB, TG3AA and TG3BB, TG4AA and TG4BB of the transfer gates TG1, TG2, TG3, and TG4 by the interval D2, the electric potential of the connection parts AR12, AR22, AR32, and AR42 of the active areas AR1, AR2, AR3, and AR4 may be limited and/or prevented from being modulated by the extending parts TG1AA and TG1BB, TG2AA and TG2BB, TG3AA and TG3BB, TG4AA and TG4BB of the transfer gates TG1, TG2, TG3, and TG4.

The spacers SP1, SP2, SP3, and SP4 may surround all of the gate areas TG1A, TG2A, TG3A, and TG4A of the transfer gates TG1, TG2, TG3, and TG4 and the extending parts TG1AA and TG1BB, TG2AA and TG2BB, TG3AA and TG3BB, TG4AA and TG4BB of the transfer gates TG1, TG2, TG3, and TG4, and may be disposed to fill areas between the extending parts TG1AA and TG1BB, TG2AA and TG2BB, TG3AA and TG3BB, TG4AA and TG4BB.

The transfer gates TG1, TG2, TG3, and TG4 may include two extending parts TG1AA and TG1BB, TG2AA and TG2BB, TG3AA and TG3BB, TG4AA and TG4BB extending in the same direction as the connection parts AR12, AR22, AR32, and AR42 of the active areas AR1, AR2, AR3, and AR4, the spacers SP1, SP2, SP3, and SP4 may surround all edges of the extending parts TG1AA and TG1BB, TG2AA and TG2BB, TG3AA the TG3BB, TG4AA the TG4BB, and the edge of the extending floating diffusion areas FD1, FD2, FD3, and FD4 may overlap or be aligned to the edge of the spacers SP1, SP2, SP3, and SP4 along the height direction DR3.

Therefore, the floating diffusion area FD may be separated from the active portions AR11, AR21, AR31, AR41 of the active areas AR1, AR2, AR3, and AR4 and the gate areas TG1A, TG2A, TG3A, and TG4A of the transfer gates TG1, TG2, TG3, and TG4 overlapping the active portions AR11, AR21, AR31, AR41, on a plane formed by the intersection of the first direction DR1 and the second direction DR2. Through this, leakage current in the drain area induced by the gate voltage (the gate induced drain leakage) may be limited and/or prevented by the gate areas TG1A, TG2A, TG3A, and TG4A of the transfer gates TG1, TG2, TG3, and TG4.

The edges of the extending floating diffusion areas FD1, FD2, FD3, and FD4 may overlap or be aligned to the edges of the spacers SP1, SP2, SP3, and SP4 along the height direction DR3, thereby the distance between the gate areas TG1A, TG2A, TG3A, and TG4A of the transfer gates TG1, TG2, TG3, and TG4 and the floating diffusion area FD may be substantially constant. Accordingly, it is possible to reduce an occurrence of a characteristic deviation of the transfer transistors T1, T2, T3, and T4 that may occur due to the distance differences between the transfer gates TG1, TG2, TG3, and TG4 and the floating diffusion area FD, thereby limiting and/or preventing the occurrence of operating characteristic errors between the transfer transistors.

As the transfer gates TG1, TG2, TG3, and TG4 include the extending parts TG1AA and TG1BB, TG2AA and TG2BB, TG3AA and TG3BB, TG4AA and TG4BB, the area of the transfer gates TG1, TG2, TG3, and TG4 may be increased, and the contact area that the transfer gates TG1, TG2, TG3, and TG4 may be connected to the plurality of vias ML1 and the plurality of wire layers ML2 and ML3 of the first structure 300 may be increased, thereby transmitting the stable signal to the transfer gates TG1, TG2, TG3, and TG4.

Many features of the image sensor 1000 according to some example embodiments previously described with respect to FIGS. 1-9 are all applicable to the image sensor 1001 according to some example embodiments.

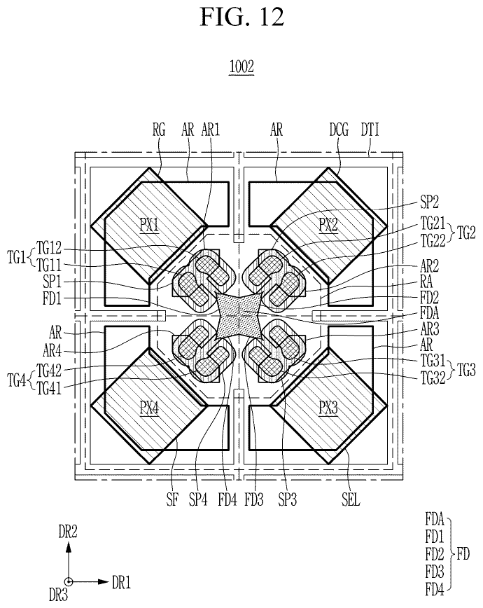

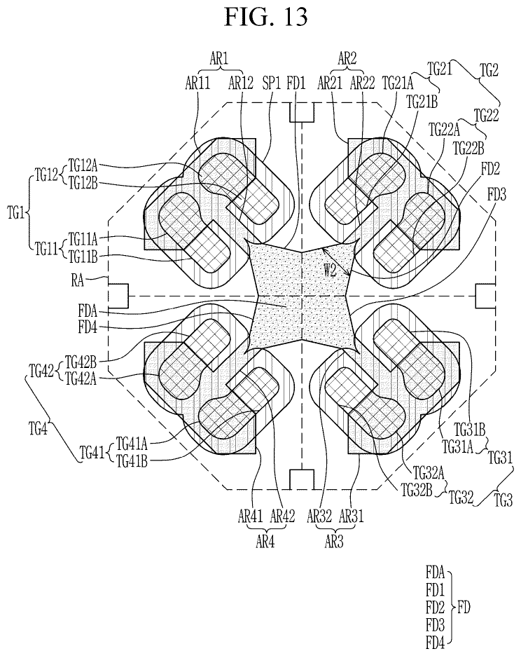

An image sensor 1002 according to some example embodiments is described with reference to FIG. 12 and FIG. 13. FIG. 12 is a top plan view of an image sensor according to another some example embodiments and FIG. 13 is an enlarged view of some areas of FIG. 12.

Referring to FIG. 10 and FIG. 11, the image sensor 1002 according to some example embodiments is similar to image sensors 1000 and 1001 according to some example embodiments described above. Detailed descriptions of the same components are omitted.

Unlike the image sensors 1000 and 1001 according to some example embodiments described previously, the second widths W2 of the extending floating diffusion areas FD1, FD2, FD3, and FD4 of the floating diffusion area FD of the image sensor 1002 according to some example embodiments is not constant, and may increase as it approaches the central floating diffusion area FDA. Through this, the area of the floating diffusion area FD may be expanded.

Similar to the image sensor 1000 according to some example embodiments described previously, according to the image sensor 1002 according to some example embodiments, the connection parts AR12, AR22, AR32, and AR42 of the active areas AR1, AR2, AR3, and AR4 may each have a first width W1, the extending parts TG11B and TG12B, TG21B and TG22B, TG31B and TG32B, TG41B and TG42B of the transfer gates TG1, TG2, TG3, and TG4 may have a first interval D1 therebetween, and the first interval D1 may be larger than the first width W1.

Intervals between the extending parts TG11B and TG12B, TG21B and TG22B, TG31B and TG32B, TG41B and TG42B of the transfer gates TG1, TG2, TG3, and TG4 and the connection parts AR12, AR22, AR32, and AR42 of the active areas AR1, AR2, AR3, and AR4 may be a second interval D2.

The connection parts AR12, AR22, AR32, and AR42 and the extending parts TG11B and TG12B, TG21B and TG22B, TG31B and TG32B, TG41B and TG42B are separated to have the second interval D2, so that an electric potential of the connection parts AR12, AR22, AR32, and AR42 of the active areas AR1, AR2, AR3, AR4 is limited and/or prevented from being modulating by two extending parts TG11B and TG12B, TG21B and TG22B, TG31B and TG32B, TG41B and TG42B of the transfer gates TG1, TG2, TG3, and TG4.

The transfer gates TG1, TG2, TG3, and TG4 include two extending parts TG11B and TG12B, TG21B and TG22B, TG31B and TG32B, TG41B and TG42B extending in the same direction as the connection parts AR12, AR22, AR32, and AR42 of the active areas AR1, AR2, AR3, and AR4, the spacers SP1, SP2, SP3, and SP4 may surround the edges of extending parts TG11B, TG12B, TG21B, TG22B, TG31B, TG32B, TG41B, and TG42B, and the edge of the extending floating diffusion areas FD1, FD2, FD3, and FD4 may overlap or be aligned to the edge of the spacers SP1, SP2, SP3, and SP4 along the height direction DR3.

Therefore, the floating diffusion area FD may be separated from the active portions AR11, AR21, AR31, and AR41 of the active areas AR1, AR2, AR3, and AR4 and the gate areas TG11A, TG12A, TG21A, TG22A, TG31A, TG32A, TG41A, and TG42A of the transfer gates TG1, TG2, TG3, and TG4 overlapping the active portions AR11, AR21, AR31, AR41, on a plane formed by the intersection of the first direction DR1 and the second direction DR2. Through this, the leakage current in the drain area induced by the gate voltage due to the gate areas TG11A, TG12A, TG21A, TG22A, TG31A, TG32A, TG41A, and TG42A of the transfer gates TG1, TG2, TG3, and TG4 (the gate induced drain leakage) may be limited and/or prevented.

The edges of the extending floating diffusion areas FD1, FD2, FD3, and FD4 may overlap or align with the edges of the spacers SP1, SP2, SP3, and SP4 along the height direction DR3, so that the distance between the gate areas TG11A, TG12A, TG21A, TG22A, TG31A, TG32A, TG41A, and TG42A of the transfer gates TG1, TG2, TG3, and TG4 and the floating diffusion area FD may be substantially constant. Accordingly, it is possible to reduce an occurrence of a characteristic deviation of the transfer transistors T1, T2, T3, and T4 that may occur due to the distance differences between the transfer gates TG1, TG2, TG3, and TG4 and the floating diffusion area FD, thereby limiting and/or preventing the occurrence of operating characteristic errors between the transfer transistors.

As the transfer gates TG1, TG2, TG3, and TG4 include the extending parts TG11B, TG12B, TG21B, TG22B, TG31B, TG32B, TG41B, and TG42B, the area of the transfer gates TG1, TG2, TG3, and TG4 may be increased, and the contact area that the transfer gates TG1, TG2, TG3, and TG4 that may be connected to the plurality of vias ML1 and the plurality of wire layers ML2 and ML3 of the first structure 300 may be increased, thereby transmitting stable signals to the transfer gates TG1, TG2, TG3, and TG4.

Many features of the image sensors 1000 and 1001 according to the previously described some example embodiments are applicable to the image sensor 1002 according to some example embodiments.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While this disclosure has been described in connection with some example embodiments, it is to be understood that the disclosure is not limited to the disclosed some example embodiments, but, on the contrary, is intended to cover various modifications and equivalent arrangements included within the spirit and scope of the appended claims.

### DESCRIPTION OF SYMBOLS

1000, 1001, 1002: image sensor
PX, PX1, PX2, PX3, PX4: pixel
PG: pixel group
CF, CF1, CF2, CF3: color filter
PD, PD1, PD2, PD3, PD4: photoelectric conversion area
FD, FDA, FD1, FD2, FD3, FD4: floating diffusion area
AR, AR1, AR2, AR3, AR4: active area
DTI: isolation pattern
TG1, TG2, TG3, TG4: transfer gate
SP1, SP2, SP3, SP4: spacer
RG, DCG, SF, SEL: gate
T1, T2, T3, T4: transfer transistor
RX: reset transistor
SX: source follower transistor
SE: selection transistor
DCX: dual conversion transistor

What is claimed is:

1. An image sensor comprising:
a substrate including a first surface and a second surface opposite the first surface;
a transfer gate on the first surface of the substrate;
a spacer on a sidewall of the transfer gate; and
a floating diffusion area inside the substrate and adjacent to the first surface of the substrate,
wherein an edge of the spacer and an edge of the floating diffusion area are at least partially aligned with each other along a height direction that is vertical with the first surface.

2. The image sensor of claim 1, further comprising:
an active area that at least partially overlaps the transfer gate, the active area being adjacent to the first surface inside the substrate,
the transfer gate including a gate area overlapping the active area and an extending part that does not overlap the active area, the extending part extending from the gate area toward the floating diffusion area.

3. The image sensor of claim 2, wherein
the edge of the floating diffusion area is aligned with the edge of the spacer that is on a sidewall of the extending part of the transfer gate along the height direction.

4. The image sensor of claim 3, wherein
the transfer gate includes a first transfer gate, and a second transfer gate spaced apart from the first transfer gate,
the first transfer gate includes a first gate area overlapping the active area and a first extending part not overlapping the active area, the first extending part extending from the first gate area toward the floating diffusion area,
the second transfer gate includes a second gate area overlapping the active area and a second extending part not overlapping the active area, the second extending part extending from the second gate area toward the floating diffusion area, and
the spacer fills an area between the first extending part and the second extending part.

5. The image sensor of claim 4, wherein
the active area includes an active portion that at least partially overlaps the transfer gate, and a connection part between the floating diffusion area and the active portion.

6. The image sensor of claim 5, wherein
on a plane parallel to the first surface of the substrate, the first extending part and the second extending part extend along a same direction as the connection part.

7. The image sensor of claim 6, wherein
on the plane parallel to the first surface of the substrate, an interval between the first extending part and the second extending part is greater than a width of the connection part.

8. The image sensor of claim 7, wherein
on the plane parallel to the first surface of the substrate, the first extending part and the second extending part are separated from the connection part.

9. The image sensor of claim 8, wherein
the floating diffusion area includes a first floating diffusion area in a same pixel area as the transfer gate, and a central floating diffusion area connected to the first floating diffusion area, the central floating diffusion area extending to another pixel area adjacent to the pixel area.

10. The image sensor of claim 9, wherein
the first floating diffusion area has a same width as the width of the connection part.

11. The image sensor of claim 9, wherein
a width of the first floating diffusion area increases from the connection part toward the central floating diffusion area.

12. The image sensor of claim 3, wherein
the extending part of the transfer gate includes a first extending part and a second extending part, the first and second extending parts extending from the gate area, and the first and second extending parts being spaced from each other, and
the spacer fills an area between the first extending part and the second extending part.

13. The image sensor of claim 12, wherein
the active area includes an active portion that at least partially overlaps the transfer gate, and a connection part between the floating diffusion area and the active portion.

14. The image sensor of claim 13, wherein
on a plane parallel to the first surface of the substrate, the first extending part and the second extending part extend in a same direction as the connection part.

15. The image sensor of claim 14, wherein
on the plane parallel to the first surface of the substrate, an interval between the first extending part and the second extending part is greater than a width of the connection part.

16. The image sensor of claim 15, wherein
on the plane parallel to the first surface of the substrate, the first extending part and the second extending part are spaced apart from the connection part.

17. The image sensor of claim 16, wherein
the floating diffusion area includes a first floating diffusion area in a same pixel area as the transfer gate, and a central floating diffusion area connected to the first floating diffusion area, the central floating diffusion area extending to another pixel area adjacent to the pixel area.

18. The image sensor of claim 17, wherein
the first floating diffusion area has a same width as the width of the connection part.

19. An image sensor manufacturing method comprising:
forming a transfer gate on a first surface of a substrate, the substrate including the first surface and a second surface opposite the first surface;
forming a spacer on a sidewall of the transfer gate; and
forming a floating diffusion area by doping an impurity on the first surface of the substrate using a mask, the mask having an opening that exposes at least a portion of the transfer gate and the spacer,
wherein an edge of the spacer and an edge of the floating diffusion area are at least partially aligned with each other along a height direction that is vertical with the first surface.

20. The image sensor manufacturing method of claim 19, wherein
the forming of the floating diffusion area comprises doping the impurity inside a portion of an active area of the substrate adjacent to the first surface,
the forming of the transfer gate comprises forming a gate area that overlaps the active area, and forming an extending part that extends from the gate area toward the floating diffusion area without overlapping the active area, and
the edge of the floating diffusion area is aligned with the edge of the spacer that is on a sidewall of the extending part of the transfer gate along the height direction.
